(19) United States
(12) Patent Application Publication
(10) Pub. No.: US 2024/0030359 A1
(43) Pub. Date: Jan. 25, 2024

(54) SEMICONDUCTOR DEVICE WITH CAPACITOR AND METHOD FOR FORMING THE SAME

(71) Applicant: TAIWAN SEMICONDUCTOR MANUFACTURING COMPANY LTD., HSINCHU (TW)

(72) Inventors: SHU-HUI SU, TAIPEI COUNTY (TW); HSIN-LI CHENG, TAIPEI COUNTY (TW); YINGKIT FELIX TSUI, CUPERTINO, CA (US); YU-CHI CHANG, KAOHSIUNG CITY (TW); HSUAN-NING SHIH, TAIPEI COUNTY (TW)

(21) Appl. No.: 17/813,951

(22) Filed: Jul. 21, 2022

(51) Int. Cl. H01L 29/94; H01L 23/522; H01L 23/528; H01L 27/108; H01L 29/66

(52) U.S. Cl. CPC H01L 29/945; H01L 23/5226; H01L 23/5283; H01L 27/10829; H01L 27/10861; H01L 29/66181

(57) ABSTRACT

The present disclosure provides a semiconductor device, including a first semiconductor structure and a second semiconductor structure. Each of the first semiconductor structure and the second semiconductor structure includes a substrate; a through silicon via, penetrating the substrate; and a deep trench capacitor, disposed in the substrate, separated from the TSV by a distance. The deep trench capacitor includes a stack, including a dielectric layer between a pair of conductive layers in a trench; and an insulating layer, covering the stack and the trench. The insulating layer surround a plurality of voids in the trench.

### BACKGROUND

A capacitor is a device including a dielectric layer sandwiched by a pair of electrodes. A capacitor may be employed as a charge storage unit in a dynamic random access memory (DRAM), may be provided as a stand-alone semiconductor chip, or may be embedded in a system-on-chip (SoC) semiconductor chip. In addition, a capacitor may also be employed in a variety of circuit applications such as a charge pump or a capacitive analog component in a radio-frequency (RF) circuit.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures can be arbitrarily increased or reduced for clarity of discussion.

FIG. 1A is a schematic cross-sectional view of a semiconductor structure, in accordance with some embodiments of the present disclosure.

FIG. 1B is a schematic cross-sectional view of a semiconductor device, in accordance with some embodiments of the present disclosure.

FIG. 2 is a flow diagram showing a method of fabricating the semiconductor device in FIG. 1B, in accordance with some embodiments of the present disclosure.

FIGS. 3, 4, 5A to 5D, 6A, 6B, 7A to 7E, 8A to 8F, 9, 10A, 10B, 11A, 11B, 12A, 12B, 13, 14, 15A, 15B and 16 are schematic cross-sectional views illustrating sequential operations of the method shown in FIG. 2, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A trench capacitor is a small three-dimensional device formed by etching a trench into a semiconductor substrate. A deep trench capacitor (DTC) is used to provide capacitance to various integrated circuits (ICs). Deep trench capacitors can be used in a variety of semiconductor chips for high areal capacitance and low device leakage. Typically, a deep trench capacitor provides a capacitance in the range from 4 femtoFarad (fF) to 120 fF. An advantage of using the deep trench capacitor over package structures is that it can be freely placed as close as possible to the desired processing units. Additionally, the deep trench capacitor can also provide higher capacitance per unit area. Deep trench capacitors are commonly embedded in integrated passive devices (IPDs) and used in place of ceramic capacitors to reduce the size of semiconductor device, reduce the cost of semiconductor devices, increase the functionality of semiconductor devices, or any combination of the foregoing.

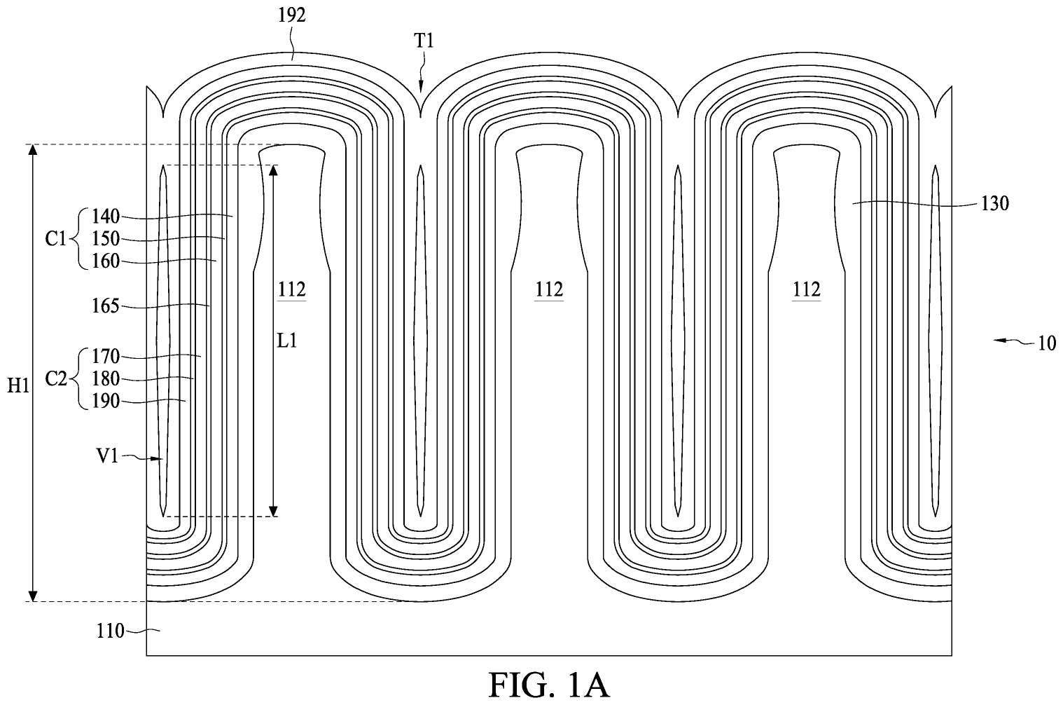

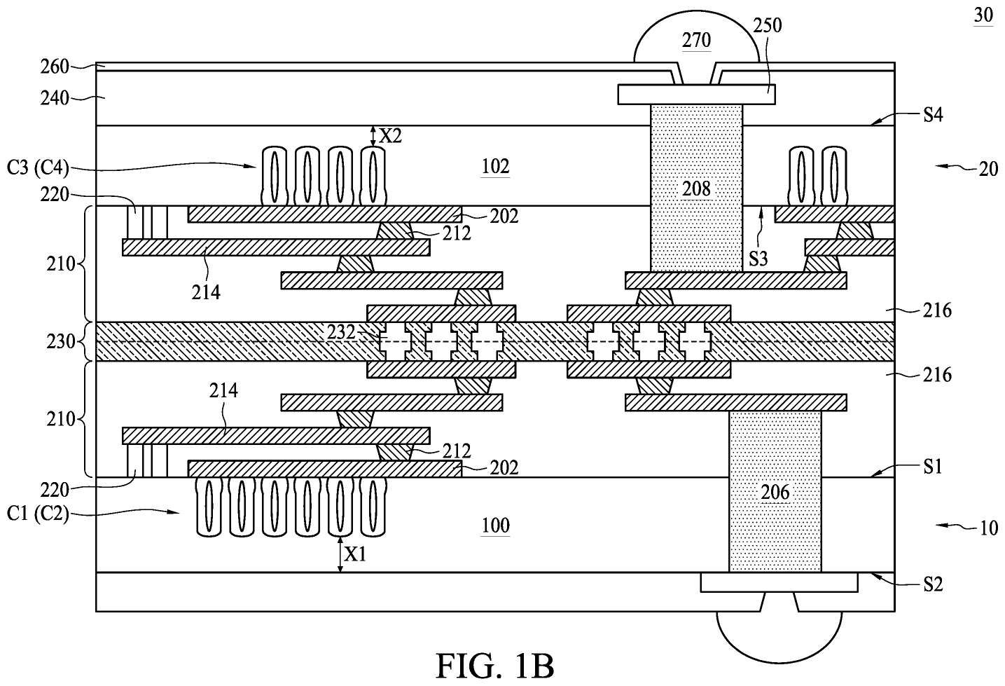

FIG. 1A is a schematic cross-sectional view of a semiconductor structure 10 which includes a doped region 110. Multiple trenches T1 and multiple fins 112 are formed within the doped region 110. Each fin 112 may be conductive due to its containing of conductive ions or dopants. The trench T1 has a depth H1 that is substantially equal to a height of the fin 112. A liner layer 130 is conformally disposed on surfaces of the fins 112. A first metal-insulator-metal (MIM) capacitor C1 is disposed in the trenches T1 and conformally over the liner layer 130. The first MIM capacitor C1 includes a first conductive layer 140, a first dielectric layer 150 conformally over the first conductive layer 140, and a second conductive layer 160 conformally over the first dielectric layer 150. A second dielectric layer 165 is conformally disposed over the second conductive layer 160. A second MIM capacitor C2 is disposed in the trenches T1 and conformally over the first MIM capacitor C1. The second MIM capacitor C2 is conformally disposed over the second dielectric layer 165. The second MIM capacitor C2 includes a third conductive layer 170, a third dielectric layer 180 conformally over the third conductive layer 170, and a fourth conductive layer 190 conformally over the third dielectric layer 180. The first MIM capacitor C1 and the second MIM capacitor C2 are deep trench capacitors separated by the second dielectric layer 165. A thickness of each of the conductive layers 140, 160, 170 and 190 may be between about 200 angstroms (Å) and about 300 Å. A thickness of each of the dielectric layers 150, 165 and 180 may be less than 100 Å. The conductive layers 140, 160, 170 and 190 are alternately arranged with the dielectric layers 150, 165 and 180 and forming a stack in the trenches T1.

The second MIM capacitor C2 is disposed in parallel to and vertically over the first MIM capacitor C1. The first MIM capacitor C1 and the second MIM capacitor C2 extend over the doped region 110 of a substrate (not shown). An insulating layer 192 is disposed in the trenches T1 and over the second MIM capacitor C2. Top portions of the insulating layer 192, the first MIM capacitor C1 and the second MIM capacitor C2 seal the trenches T1. Portions of the insulating layer 192 in respective trenches T1 are substantially hollow. Multiple voids (or air gaps) V1 are formed inside the insulating layer 192. The size of the voids V1 may be different in different embodiments of the present disclosure. The void V1 may have different diameters at its different heights. A longitudinal length L1 of the void V1 may be about 0.1 to about 0.98 times the depth H1 of the trench T1 or the height of the fin 112.

FIG. 1B is a schematic cross-sectional view of a semiconductor device 30. The semiconductor device 30 includes the semiconductor structure 10 shown in FIG. 1A bonded with a semiconductor structure 20. The semiconductor structure 20 is similar to the semiconductor structure 10 with a difference that the relative position of the MIM capacitors C3, C4 and the TSV 208 of the semiconductor structure 20 is different from the relative position of the MIM capacitors C1, C2 and the TSV 206 of the semiconductor structure 10. An interconnect structure 210 is disposed on the semiconductor structure 10, and another interconnect structure 210 is disposed on the semiconductor structure 20. The interconnect structure 210 includes multiple vertical conductive vias (such as 212) and multiple horizontal conductive lines (such as 214) which are surrounded by a dielectric layer 216. A bonding layer 230 is disposed between the two interconnect structures 210. The bonding layer 230 bonds the interconnect structure 210 on the semiconductor structure 10 and the interconnect structure 210 on the semiconductor structure 20. The bonding layers 230 includes multiple hybrid bonding structures (HBSs) 232 embedded in a dielectric layer 234. The bonding layer 230 and the two interconnect structures 210 may be referred to as a connecting layer which connects the semiconductor structure 10 to the semiconductor structure 20. An encapsulation layer 240 respectively overlays the semiconductor structures 10 and 20. A conductive feature 250 is surrounded by the encapsulation layer 240. The conductive feature 250 is embedded within the encapsulation layer 240 and in contact with the TSV 206 or 208. A passivation layer 260 is formed on the encapsulation layer 240 and the conductive feature 250. A connector 270, which can be a solder ball, is surrounded by the encapsulation layer 240. A portion of the connector 270 is embedded within the encapsulation layer 240, and another portion of the connector 270 is exposed from the encapsulation layer 240. A portion of the conductive feature 250 exposed from the encapsulation layer 240 is coupled to the connector 270. The MIM capacitors C1, C2 and C3, C4 can be electrically coupled to their respective connector 270 through the interconnect structure 210 and the conductive feature 250.

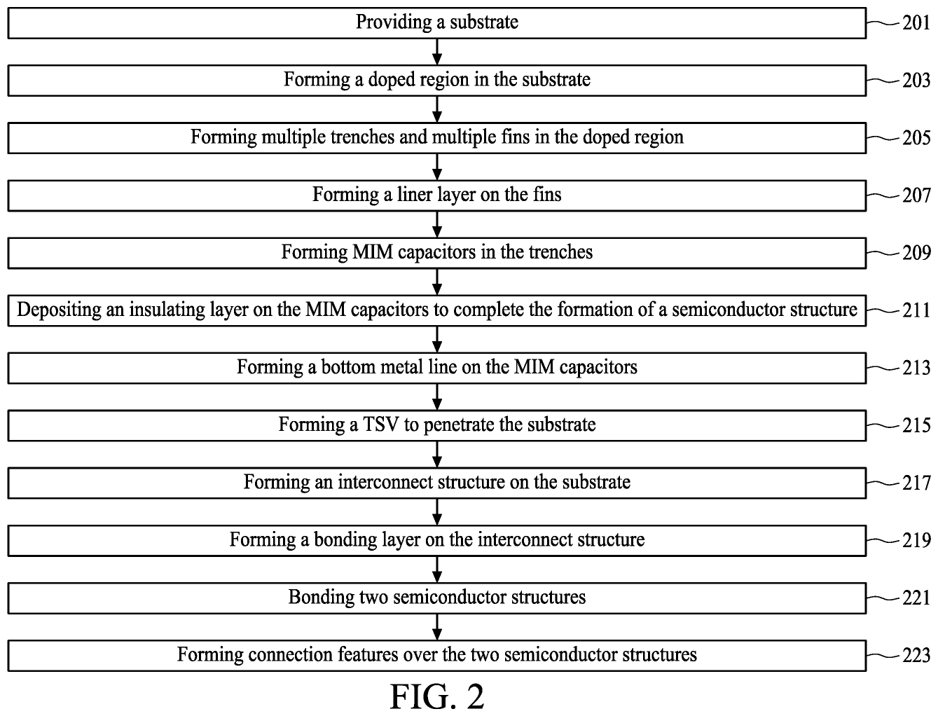

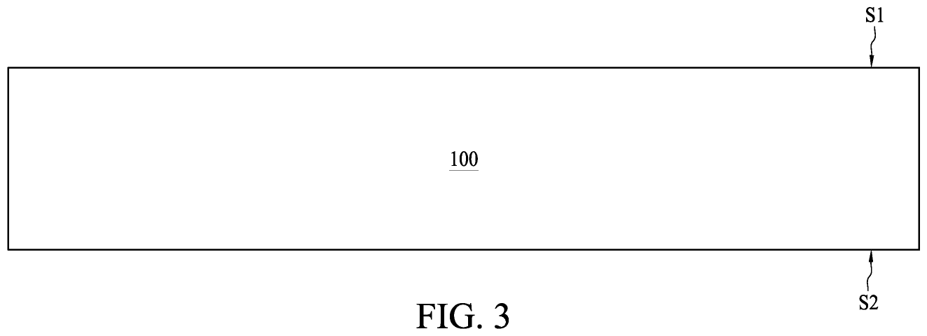

FIG. 2 is a flow diagram showing a method 200 of fabricating the semiconductor device 30 in FIG. 1B. FIGS. 3, 4, 5A to 5D, 6A, 6B, 7A to 7E, 8A to 8F, 9, 10A, 10B, 11A, 11B, 12A, 12B, 13, 14, 15A, 15B and 16 are schematic cross-sectional views illustrating sequential operations of the method 200 shown in FIG. 2.

In operation 201 of FIG. 2, a substrate 100 is provided, as shown in FIG. 3. The substrate 100 has a first surface S1 and a second surface S2 opposite to the first surface S1. The substrate 100 may be a silicon wafer. In some embodiments, the substrate 100 is a silicon-on-insulator (SOI) substrate, a polysilicon substrate, or an amorphous silicon substrate. The substrate 100 may include a suitable elementary semiconductor, such as germanium (Ge) or diamond. In some embodiments, the substrate 100 includes a compound semiconductor, such as silicon germanium (SiGe), silicon carbide (SiC), gallium arsenide (GaAs), gallium nitride (GaN), indium phosphide (InP) or the like.

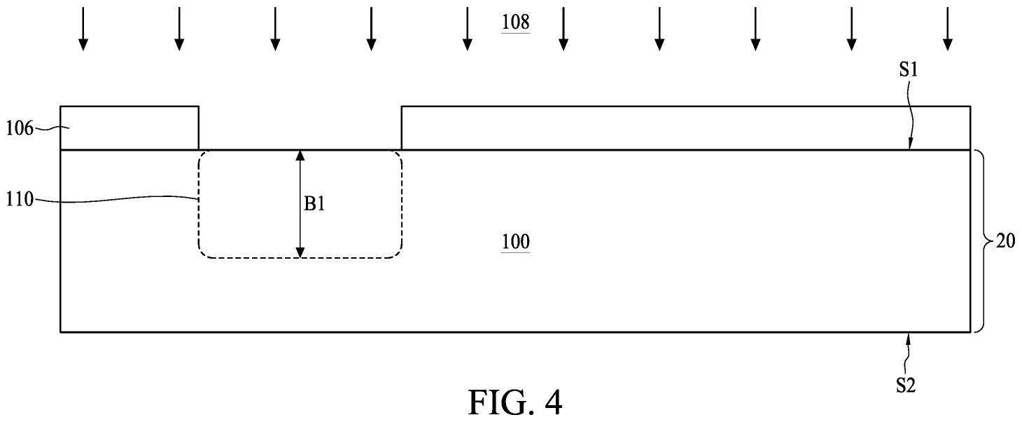

In operation 203 of FIG. 2, a doped region 110 is formed in the substrate 100, as shown in FIG. 4. An ion implantation operation may be performed on a portion of the substrate 100 to form the doped region 110. An implant mask 106 including at least one opening may be formed on the first surface S1 of substrate 100. Doping ions 108 may be implanted toward the masked substrate 100. The doping ions 108 can be P-type dopants such as boron (B), gallium (Ga) and indium (In) ions, or N-type dopants such as phosphorus (P) and arsenic (As) ions. The implant mask 106 blocks the doping ions 108 from entering the masked regions of the substrate 100, while the doping ions 108 pass through the opening of the implant mask 106 into the substrate 100. After entering from the first surface S1, the doping ions 108 in the substrate 100 may diffuse to a predetermined depth B1 of the substrate 100 to form the doped region 110. After the formation of the doped region 110, the implant mask 106 is removed.

The doped region 110 may be a P-type conductive region or an N-type conductive region. In some embodiments, the doped region 110 includes a p-n junction. For example, dopants of a first conductivity type may be doped into the substrate 100 at a first depth range. Subsequently, dopants of a second conductivity type may be doped into the substrate 100 at a second depth range adjacent to the first depth range to form the p-n junction at an interface between the first depth range and the second depth range. The second depth range may be less than the first depth range. The second conductivity type may be opposite to the first conductivity type. For example, the first conductivity type can be p-type and the second conductivity type can be n-type, or vice versa.

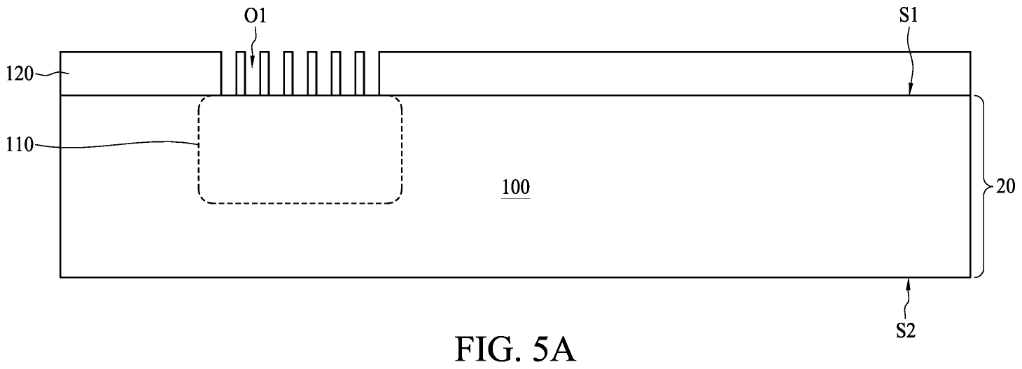

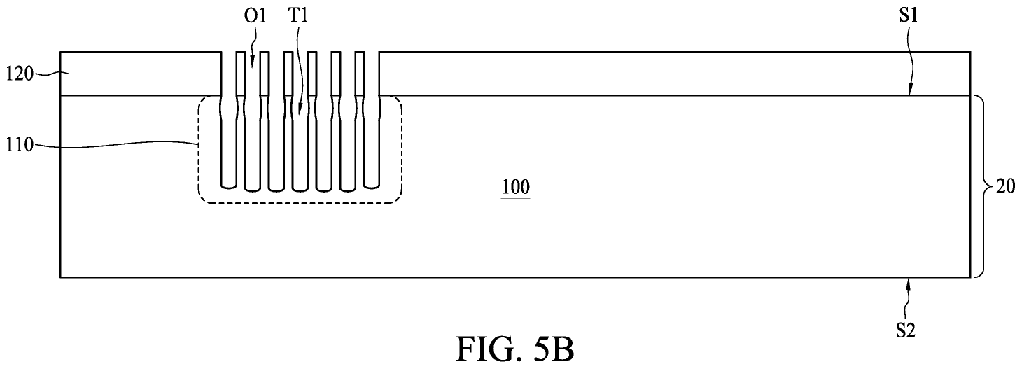

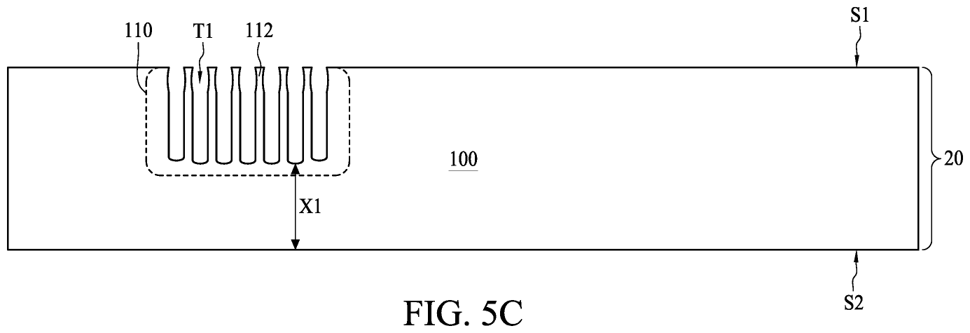

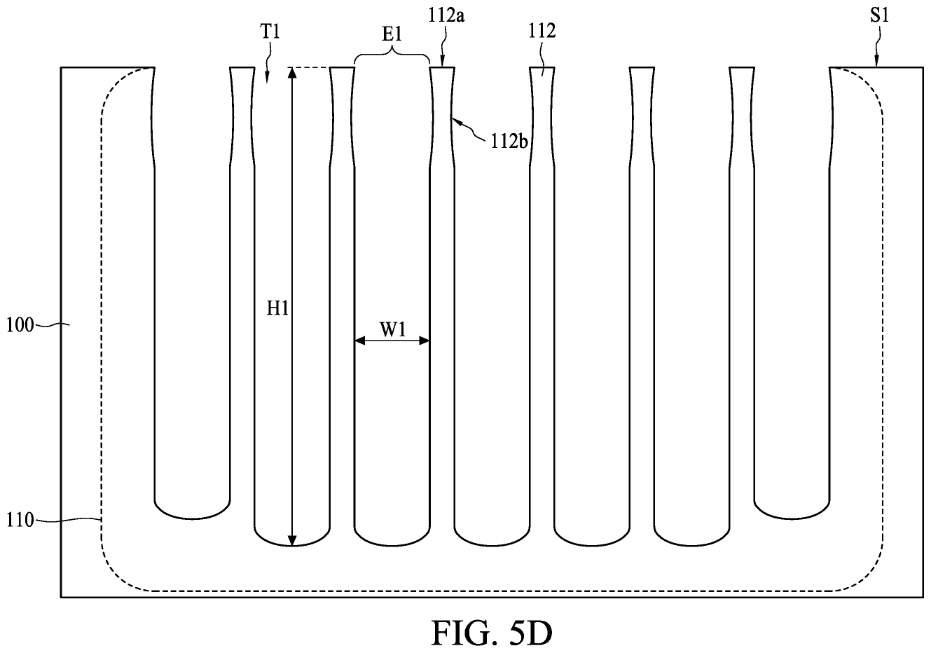

In operation 205 of FIG. 2, multiple trenches T1 and multiple fins 112 are formed in the doped region 110, as shown in FIGS. 5A to 5D. The doped region 110 may be patterned using one or more lithographic and etch operations. For example, a double-patterning or multi-patterning technique known in the art can be used to form the trenches T1.

Referring to FIG. 5A, a patterned mask 120 is formed on the first surface S1 of the substrate 100. The patterned mask 120 may be a patterned photoresist or a nitride hard mask. The patterned mask 120 may include parallel strips separated by multiple openings O1 that expose portions of the underlying doped region 110.

Referring to FIG. 5B, a dry etch or a reactive ion etch (RIE) operation is performed on the substrate 100 using the patterned mask 120 as an etching mask. The doped region 110 is etched through the openings O1 of the patterned mask 120 until multiple trenches T1 are formed.

Referring to FIG. 5C, after the patterned mask 120 is removed, the fins 112 are exposed. The fins 112 may be alternately arranged with the trenches T1. The fins 112 may be arranged in parallel strips and protruded from a lower portion of the doped region 110. In some embodiments, a distance X1 between a bottommost point of the trench T1 and the second surface S2 is greater than 0.8 micrometers (μm).

FIG. 5D is an enlarged view of FIG. 5C showing the trenches T1 and the fins 112 are formed in the doped region 110. Each trench T1 may have an entrance E1 coplanar with the first surface S1 of the substrate 100. The fins 112 may have respective top surfaces 112a and sidewall surfaces 112b arranged between neighboring trenches T1. The top surface 112a of each fin 112 may be coplanar with the first surface S1 of the substrate 100. The sidewall surfaces 112b may be even or uneven surfaces. The trenches T1 may respectively extend downwardly from the first surface S1 of the substrate 100 into bottom portions of the doped region 110. The trench T1 has a depth H1 as measured from the first surface S1 of the substrate 100. The depth H1 of the trench T1 is approximately equal to a height of the fin 112. The trench T1 has a width W1 between neighboring fins 112. In some embodiments, the depth H1 is about 20 μm to about 40 μm. In some embodiments, the width W1 of an individual trench T1 is about 0.3 μm to about 0.7 μm. The trenches T1 may each have a high depth-to-width aspect ratio, that is, a ratio of the depth H1 to the width W1 is relatively high. In some embodiments, the aspect ratio of the trench T1 ranges from about 20:1 to about 140:1 such that the trench T1 may be referred to as deep trenches (DT). The trenches T1 may be configured for formation of deep trench capacitors. The high aspect ratios are used to increase the capacitance density of the deep trench capacitors.

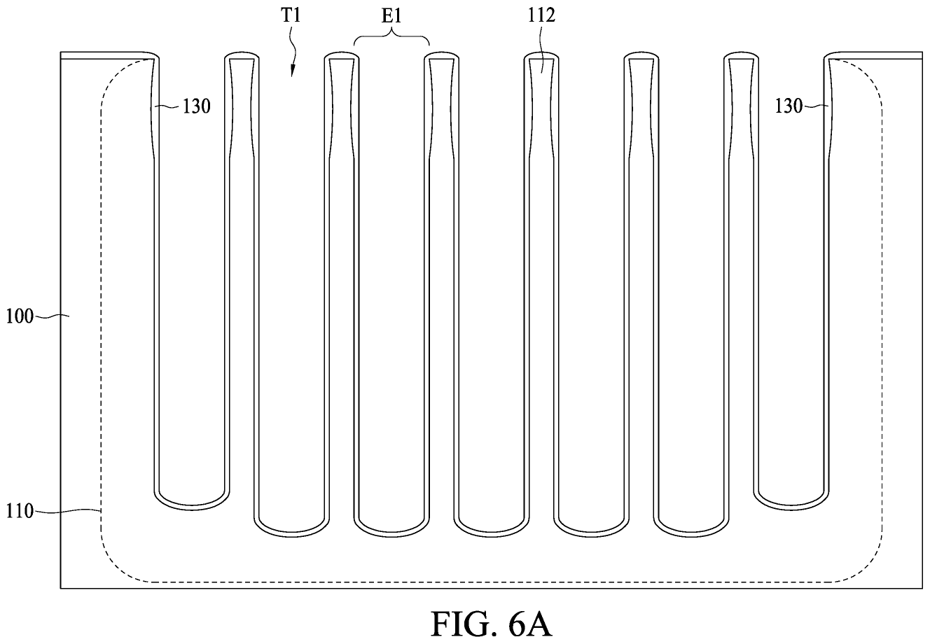

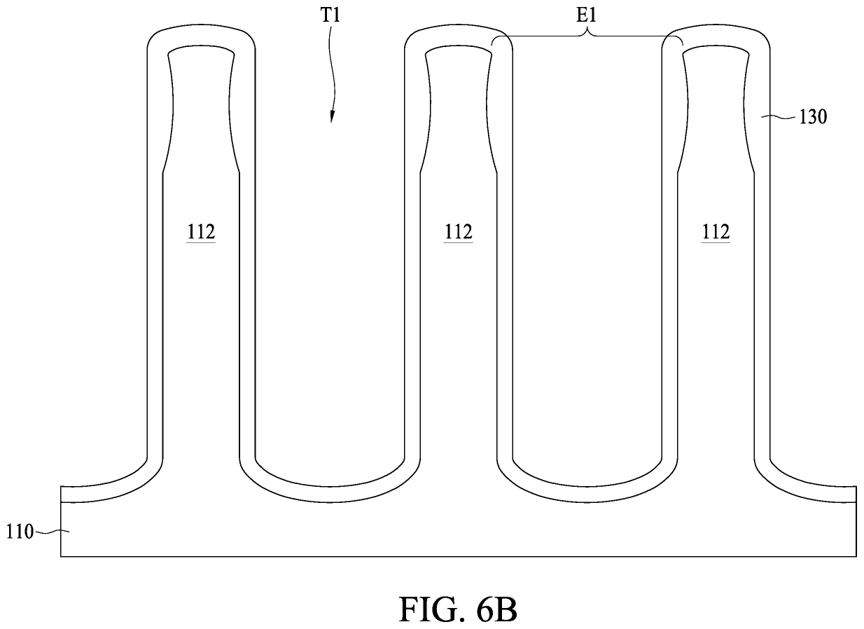

In operation 207 of FIG. 2, a liner layer 130 is formed on the fins 112, as shown in FIG. 6A. The formation of the liner layer 130 may use a thermal oxidation operation. For example, oxygen gas (02) may be reacted with the fins 112 under a high temperature in a furnace. The silicon material of the fins 112 may be oxidized to form silicon oxide on the top surfaces 112a and the sidewall surfaces 112b of the fins 112.

FIG. 6B is an enlarged view of FIG. 6A showing the liner layer 130 is formed on the fins 112. In some embodiments, the liner layer 130 is conformally formed on surfaces of the fins 112. The liner layer 130 may be grown to different widths at different heights so as to create an even and smooth surface over the fins 112 for subsequent operations.

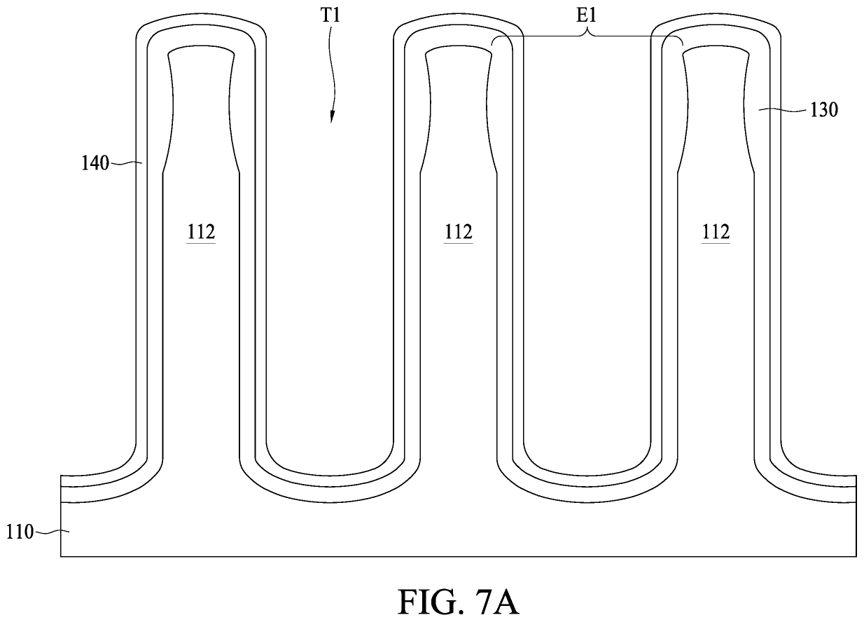

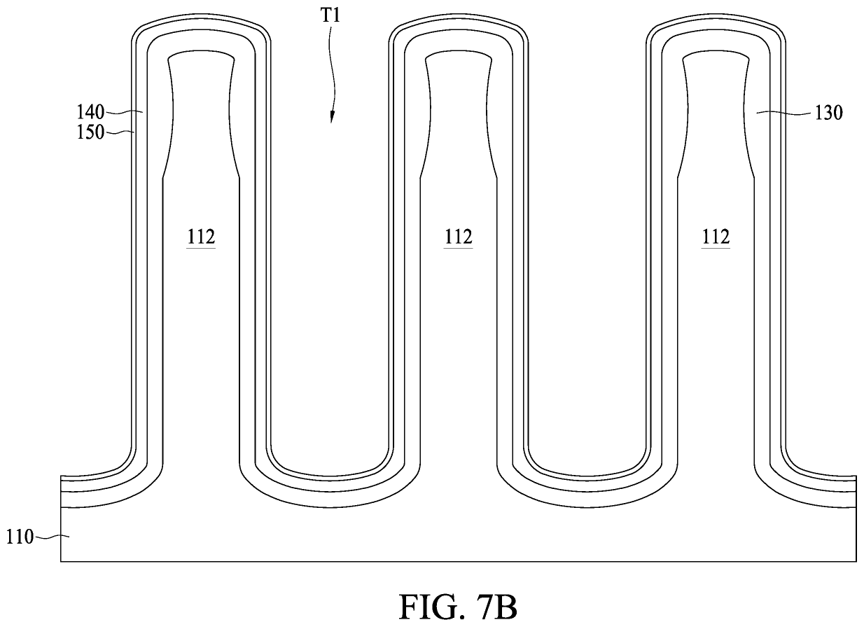

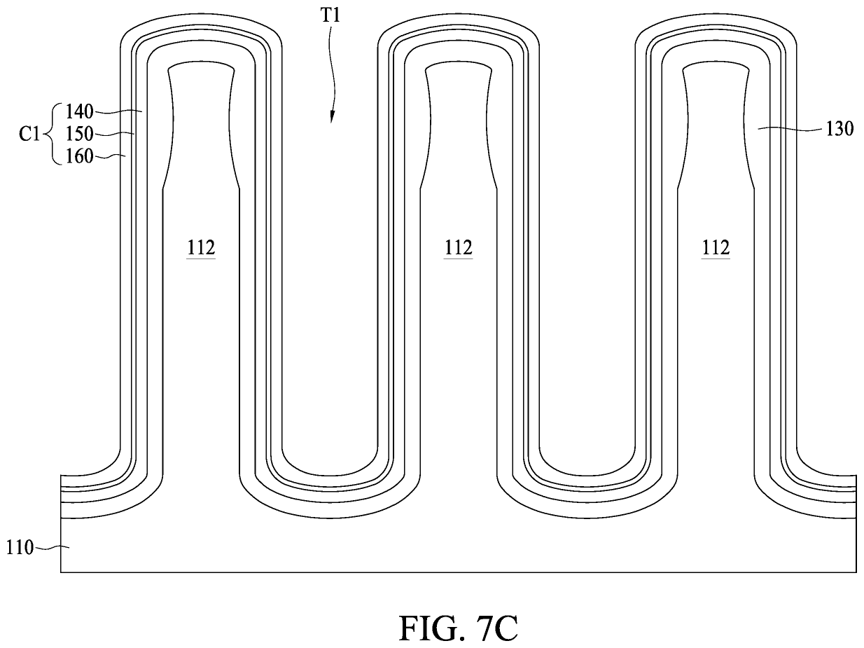

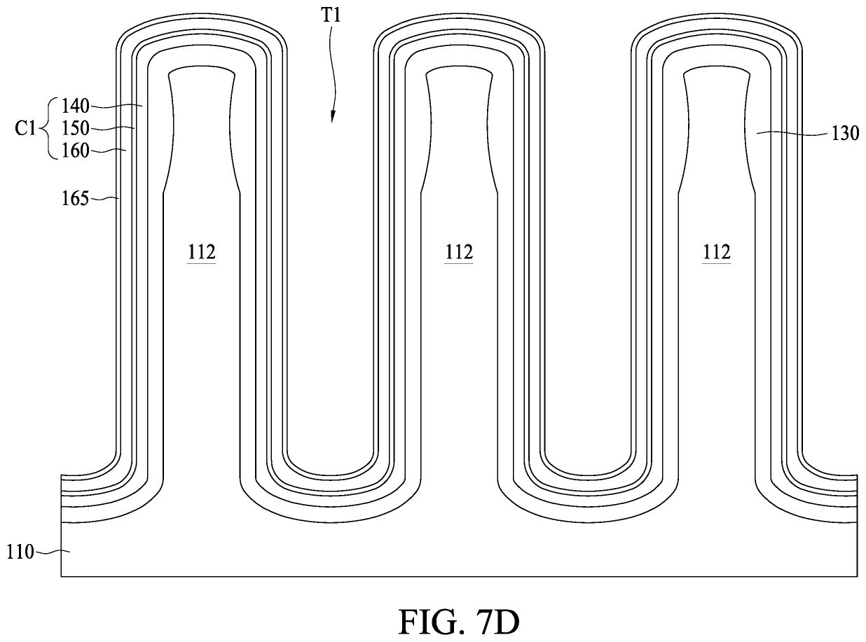

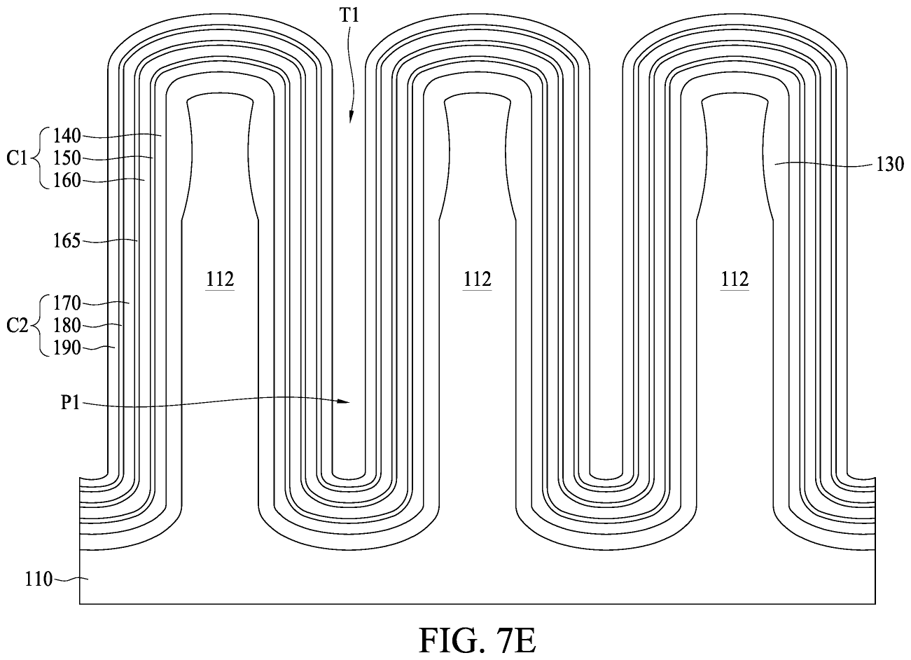

In operation 209 of FIG. 2, metal-insulator-metal (MIM) capacitors C1 and C2 are formed in the trenches T1, as shown in FIGS. 7A to 7E. Referring to FIG. 7A, a first conductive layer 140 is deposited on the liner layer 130. In some embodiments, the first conductive layer 140 is conformally formed in the trenches T1 and over the liner layer 130 using a physical vapor deposition (PVD) operation or an atomic layer deposition (ALD) operation. The first conductive layer 140 may include polysilicon or metal, such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au) or a combination thereof. In some embodiments, the first conductive layer 140 includes titanium nitride (TiN), tantalum nitride (TaN), aluminum copper (AlCu) or other titanium or tantalum based compounds having an appropriate conductive work function. In some embodiments, a thickness of the first conductive layer 140 is between about 100 angstroms (Å) and about 300 Å.

Referring to FIG. 7B, a first dielectric layer 150 is deposited on the first conductive layer 140. In some embodiments, the first dielectric layer 150 is conformally formed in the trenches T1 and over the first conductive layer 140 using a chemical vapor deposition (CVD) operation or an ALD operation. In some embodiments, the first dielectric layer 150 includes one or more dielectric materials with high dielectric constants (high k) greater than that of silicon oxide (k>3.9). The first dielectric layer 150 may be made of SiN, SiON, Al₂O₃, TiO₂, Ta₂O₅, HfO₂, ZrO₂, HfZrO, HfOₓN_{y}, HfSiₓO_{y}, ZrOₓN_{y}, ZrSiₓO_{y}, HfSiₓO_{y}N_{z}, La₂O₃, Pr₂O₃ or other suitable materials. In some embodiments, a thickness of the first dielectric layer 150 is less than 100 Å. The first dielectric layer 150 may have a dielectric constant ranging between 4 and 1000, with some embodiments having a dielectric constant of approximately 20. In some other embodiments, the first dielectric layer 150 includes a dielectric stack such as an oxide-nitride-oxide (“ONO”) structure. In such embodiments, the thickness of the first dielectric layer 150 is about 20 angstroms (Å) to about 1000 Å according to the composition of oxide and nitride.

Referring to FIG. 7C, a second conductive layer 160 is deposited on the first dielectric layer 150 to complete the first MIM capacitor C1. In some embodiments, the second conductive layer 160 is conformally formed in the trenches T1 and over the first dielectric layer 150 using the same operation used to form the first conductive layer 140. The material and thickness of the second conductive layer 160 may be the same as or similar to those of the first conductive layer 140. The first conductive layer 140, the first dielectric layer 150 and the second conductive layer 160 may form the first MIM capacitor C1. The first MIM capacitor C1 may have a capacitance capable of storing a high volume of electrons. The first conductive layer 140 and the second conductive layer 160 may respectively function as a bottom electrode and a top electrode of the first MIM capacitor C1. The first dielectric layer 150 which insulates the bottom electrode and the top electrode may be referred to as a capacitor dielectric. Capacitance of first MIM capacitor C1 may be derived by the following equation:

$$C = {ε}_{r} {ε}_{0} \frac{A}{d}$$

In the above equation, A is an area of overlap of a pair of conductive capacitor plates (i.e., the area of overlap of the first conductive layer 140 and the second conductive layer 160). εᵣ is the relative static permittivity of the material between the plates (i.e., the relative static permittivity of the first dielectric layer 150), ε₀ is the electric constant, which is about 8.854×10⁻² F m⁻¹; and d is the distance separating the conductive capacitor plates.

As a result, when the first dielectric layer 150 becomes thinner (thus decreasing the distance between the conductive layers 140 and 160), or when the trenches T1 become deeper (thus increasing the overlapping area of the conductive layers 140 and 160), the capacitance of first MIM capacitor C1 may be increased.

Referring to FIG. 7D, a second dielectric layer 165 is formed on the second conductive layer 160. In some embodiments, the second dielectric layer 165 is conformally formed in the trenches T1 and over the second conductive layer 160 using the similar operation used to form the first dielectric layer 150. The material or configuration of the second dielectric layer 165 may be the same as or similar to those of the first dielectric layer 150. The thickness of the second dielectric layer 165 may be the same as or greater than that of the first dielectric layer 150.

Referring to FIG. 7E, a second MIM capacitor C2 is formed on the second dielectric layer 165. The formation of the second MIM capacitor C2 may be similar to that of the first MIM capacitor C1 showed from FIGS. 7A to 7C. The second MIM capacitor C2 includes a third conductive layer 170 and a fourth conductive layer 190, and a third dielectric layer 180 disposed therebetween. In some embodiments, the third conductive layer 170 is conformally formed over the second dielectric layer 165, the third dielectric layer 180 conformally formed over the third conductive layer 170, and the fourth conductive layer 190 conformally formed over the third dielectric layer 180. The third conductive layer 170, the third dielectric layer 180 and the fourth conductive layer 190 may be formed in succession using the same methods for forming the first conductive layer 140, the first dielectric layer 150 and the second conductive layer 160, respectively. The second MIM capacitor C2 may have a capacitance capable of storing a high volume of electrons. The third conductive layer 170 and the fourth conductive layer 190 may respectively function as a bottom electrode and a top electrode of the second MIM capacitor C2. The third dielectric layer 180 which insulates the bottom electrode and the top electrode may be referred to as a capacitor dielectric.

Still referring to FIG. 7E, in some embodiments, the trenches T1 are not completely filled by the conductive layers and dielectric layers of the MIM capacitors C1 and C2. That is, each trench T1 may have some space P1 over the fourth conductive layer 190. The trenches T1 are still open and not sealed at this stage. In some embodiments, the space P1 is over the second MIM capacitor C2.

In some embodiments, the first MIM capacitor C1 and the second MIM capacitor C2 are deep trench capacitors disposed in parallel and vertically over one another. The bottom electrode of the second MIM capacitor C2 is directly disposed over the top electrode of the first MIM capacitor C1. The second dielectric layer 165 may physically and electrically isolates the first MIM capacitor C1 and the second MIM capacitor C2. The first MIM capacitor C1 and the second MIM capacitor C2 may form a double-MIM capacitor in the doped region 110 of the substrate 100. In some embodiments, the number of deep trench capacitors can be increased. For example, more MIM capacitors may be stacked over the second MIM capacitor C2. In some other embodiments, the number of deep trench capacitors can be decreased. For example, only the first MIM capacitor C1 may be formed in the trenches.

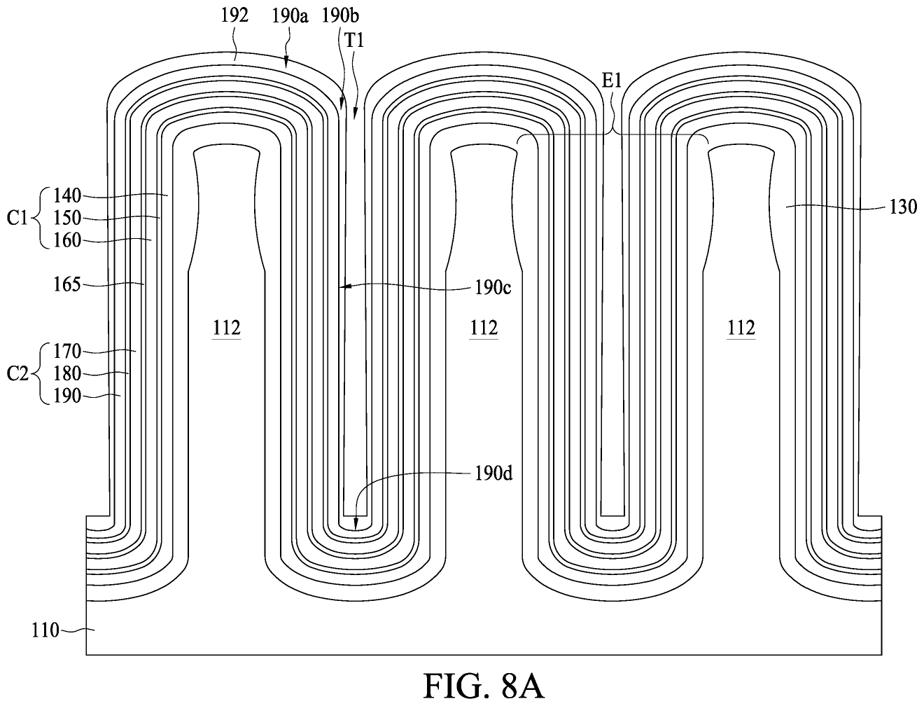

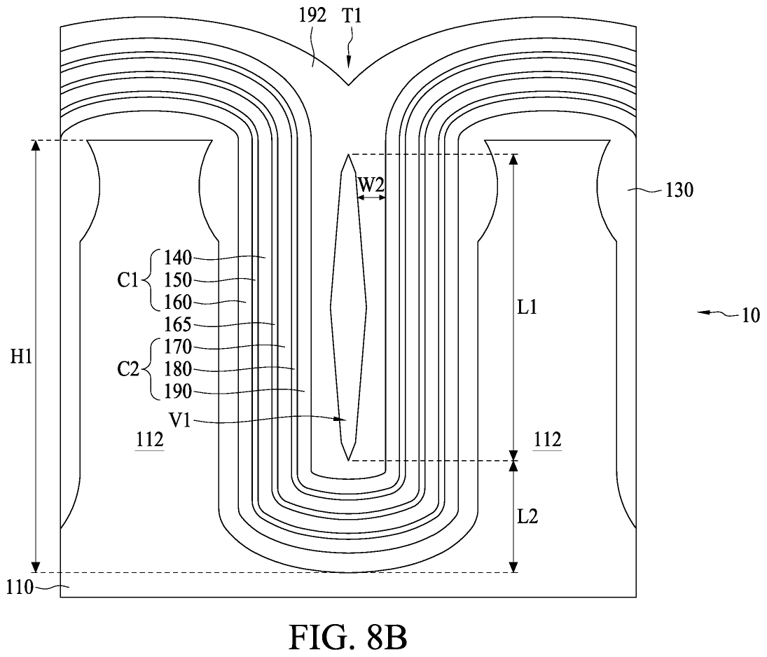

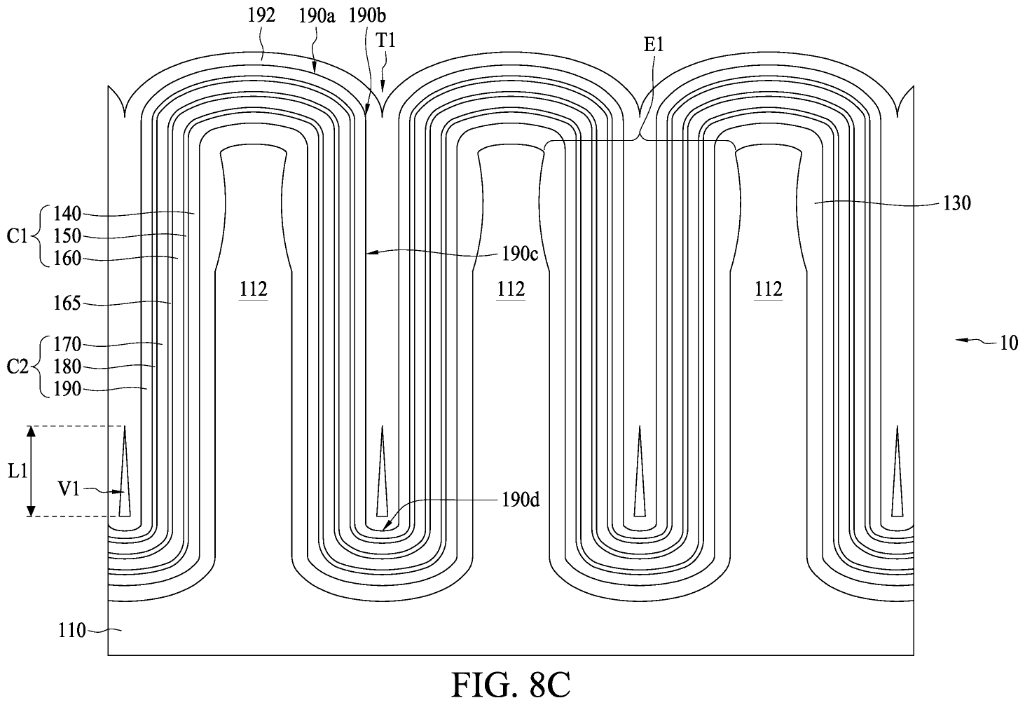

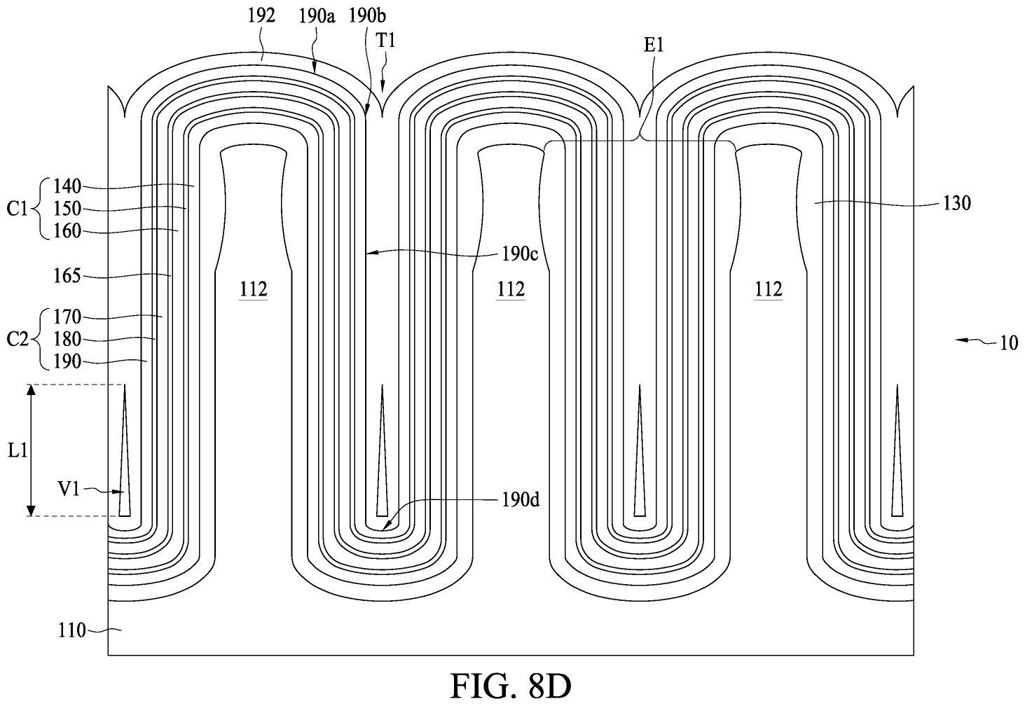

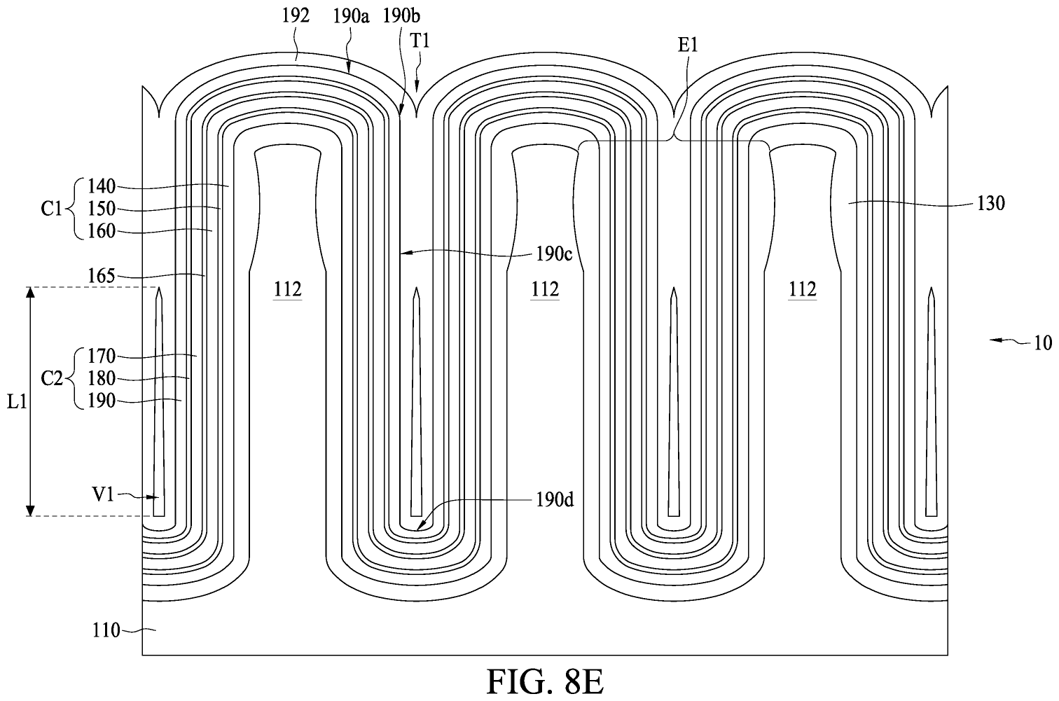

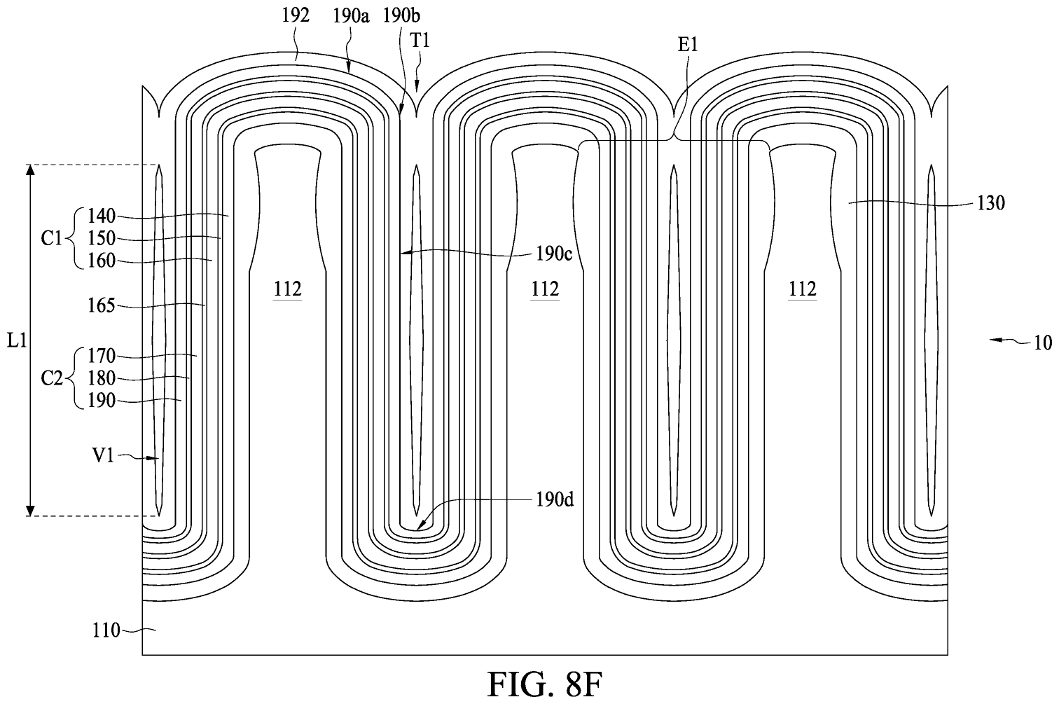

In operation 211 of FIG. 2, an insulating layer 192 is deposited on the MIM capacitors C1 and C2 to complete the formation of a semiconductor structure 10, as shown in FIGS. 8A to 8F. The trenches T1 must be sealed to prevent materials used in subsequent operations such as photoresist or water from entering the trenches T1. The insulating layer 192 is used to seal the trenches T1. Referring to FIG. 8A, the insulating layer 192 may be deposited on the fourth conductive layer 190 using a CVD operation or an ALD operation. The material of the insulating layer 192 may include silicon oxide, silicon nitride, silicon carbide, undoped silicate glass (USG), boro-silicate glass (BSG), tetraethoxysilane (TEOS), a low-k material, or materials of an anti-reflection layer. In some embodiments, the insulating layer 192 is formed on a top surface 190a, a corner 190b, a sidewall surface 190c and a bottom surface 190d of the fourth conductive layer 190 of the second MIM capacitor C2. In some embodiments, the second MIM capacitor C2 is disposed in parallel to and vertically over the first MIM capacitor C1. In some embodiments, the first MIM capacitor C1 and the second MIM capacitor C2 extend over the doped region 110 and the substrate 100. The insulating layer 192 covers the second MIM capacitor C2.

FIG. 8B is an enlarged view of FIG. 8A after all the trenches T1 are sealed by the insulating layer 192. Since the aspect ratio of the trenches T1 is extremely high, when deep trench capacitors are formed in the substrate 100, the substrate 100 may be subject to a significant stress. In some embodiments, when the trenches T1 are sealed by the insulating layer 192, a void or air gap V1 is left in the insulating layer 192 within each of the trenches T1. That is, the insulating layer 192 in the trenches T1 may be hollow. In some embodiments, the voids V1 are used to release the stress of the substrate 100 and prevent the wafer warpage. The formation of the voids V1 may be controlled by adjusting process parameters of the deposition operation for forming the insulating layer 192. At this stage, the formation of the semiconductor structure 10 including MIM capacitors is finished. Although not specifically shown, in some embodiments, some processing units or electronic components may be disposed on the substrate 100 of the semiconductor structure 10. The processing units are configured to perform high-speed computing. In some embodiments, the processing units can be anyone or combination of the following: logic, memory, integrated passive device (IPD), micro electro mechanical systems (MEMS), digital signal processor (DSP), microcontroller (MCU), central-processing unit (CPU) or a plurality of parallel processors relating the parallel processing environment to implement the operating system, firmware, driver and/or other applications of an electronic apparatus.

Still referring to FIG. 8B, the depth H1 of the trench T1, measured from a top surface of a bottom portion of the doped region 110 to a top surface of the fins 112, may be about 20 μm to about 40 μm. A width W1 of the trench T1, measured between two facing sidewalls of adjacent fins 112, may be about 0.3 μm to about 0.7 μm. The aspect ratio of the depth H1 to the width W1 may range from about 20:1 to about 140:1. A thickness W2 of the insulating layer 192 covering the fourth conductive layer 190 within the trench T1 may be about 15 nanometers (nm) to about 22 nm. A longitudinal length L1 of the void V1 may be about 0.1 to about 0.98 times the depth H1 of the trench T1 or a height of the fin 112. The void V1 may have different diameters at different heights. A distance L2 between a bottommost point of the void V1 and a bottommost point of the trench T1 is about 80 nm to about 120 nm.

FIG. 8C to 8E show different profiles of the insulating layer 192 when all the trenches T1 are sealed. Referring to FIG. 8C, the longitudinal length L1 of the void V1 is about 10% of the depth H1 of the trench T1. Referring to FIG. 8D, the longitudinal length L1 of the void V1 is about 30% of the depth H1 of the trench T1. Referring to FIG. 8E, the longitudinal length L1 of the void V1 is about 60% of the depth H1 of the trench T1. Referring to FIG. 8E, the longitudinal length L1 of the void V1 is about 90% of the depth H1 of the trench T1.

The presence of the voids V1 with well-managed dimensions may reduce the likelihood of wafer warpage and keep the substrate 100 substantially flat. A subsequent wafer CMP operation, a photo-alignment operation, or a bonding operation can be performed smoothly on the substrate 100, thereby improving the chip yields.

Subsequent operations may be performed on the semiconductor structure 10 to fabricate interconnect structures or other devices over the first surface S1 of the substrate 100.

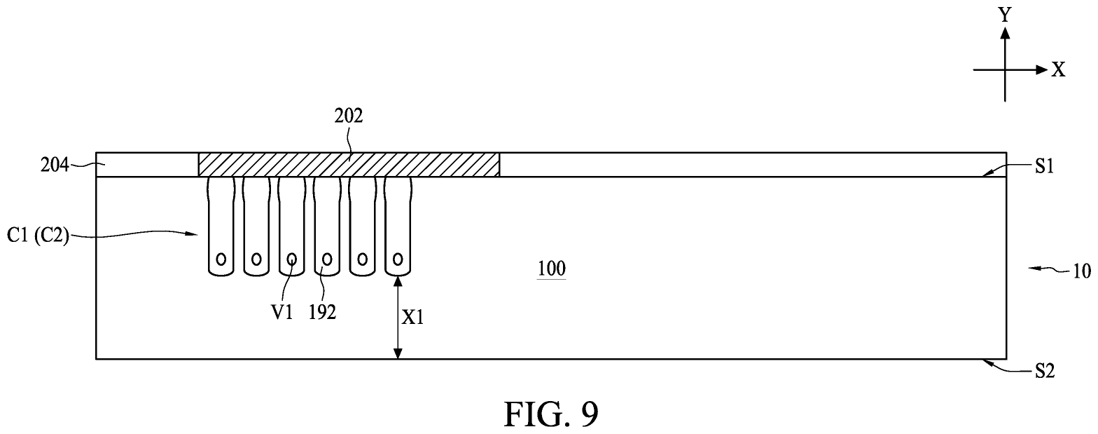

In operation 213 of FIG. 2, a bottom metal line 202 is formed on the MIM capacitors C1, C2, as shown in FIG. 9. The formation of the bottom metal line 202 may include a series of lithographic, etch and deposition operations. For example, a dielectric layer 204 may be formed on the first surface S1 of the substrate 100, followed by forming of a trench exposing at least a portion of the MIM capacitors C1, C2. Subsequently, a conductive material is deposited into the trench to form the bottom metal line 202. The bottom metal line 202 may be made of tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au) or a combination thereof. The dielectric layer 204 may be made of silicon oxide, silicon nitride, undoped silicate glass (USG), boro-silicate glass (BSG), tetraethoxysilane (TEOS) or a combination thereof. In some embodiments, the distance X1 between a bottommost point of the MIM capacitors C1, C2 and the second surface S2 is at least 0.8 μm.

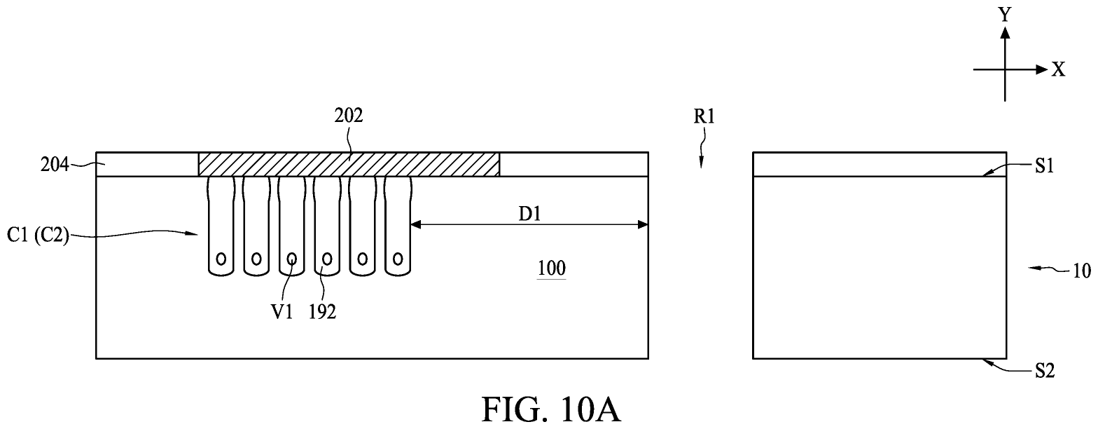

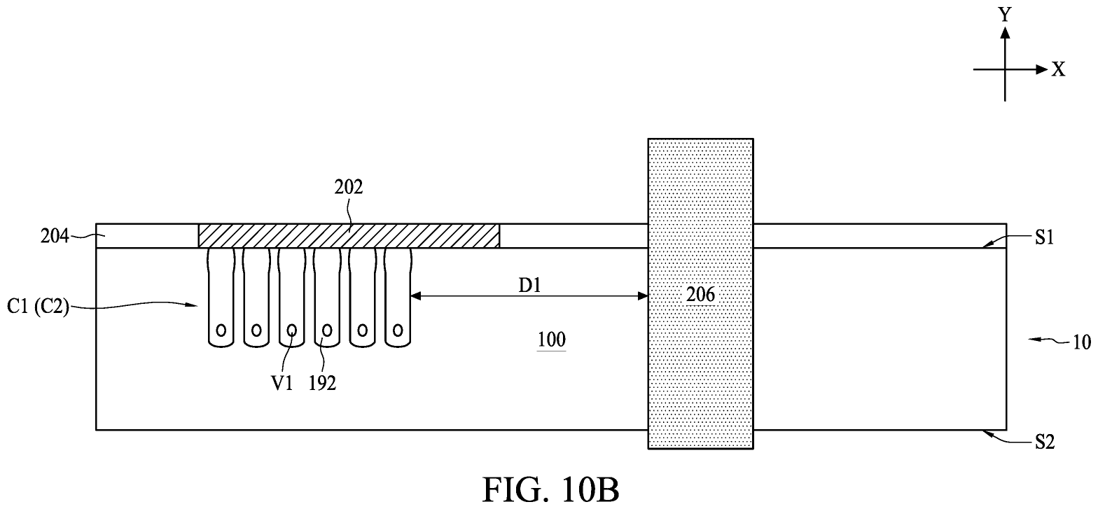

In operation 215 of FIG. 2, a through silicon via (TSV) 204 is formed to penetrate the substrate 100, as shown in FIGS. 10A, 10B, 11A, 11B, 12A and 12B. Referring to FIGS. 10A, 11A and 12A, a trench R1 is formed to penetrate the dielectric layer 204 and the substrate 100. Referring to FIGS. 10B, 11B and 12B, the TSV 206 is formed in the trench R1 by deposition of a conductive material such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au) or a combination thereof. The TSV 206 may penetrate the dielectric layer 204 and the substrate 100. In some embodiments, the MIM capacitors C1, C2 are arranged along a first direction X, and the TSV 206 extends along a second direction Y which is vertical to the first direction X. In some embodiments, the TSV 206 is spaced apart from the MIM capacitors C1, C2.

Referring to FIGS. 10A, 10B, 8C and 8D, in some embodiments, when the longitudinal length L1 of the void V1 is between about 10% and about 35% of the depth H1 of the trench T1, a predetermined distance D1 between the MIM capacitors C1, C2 and the TSV 206 is between about 1 μm and 5 μm.

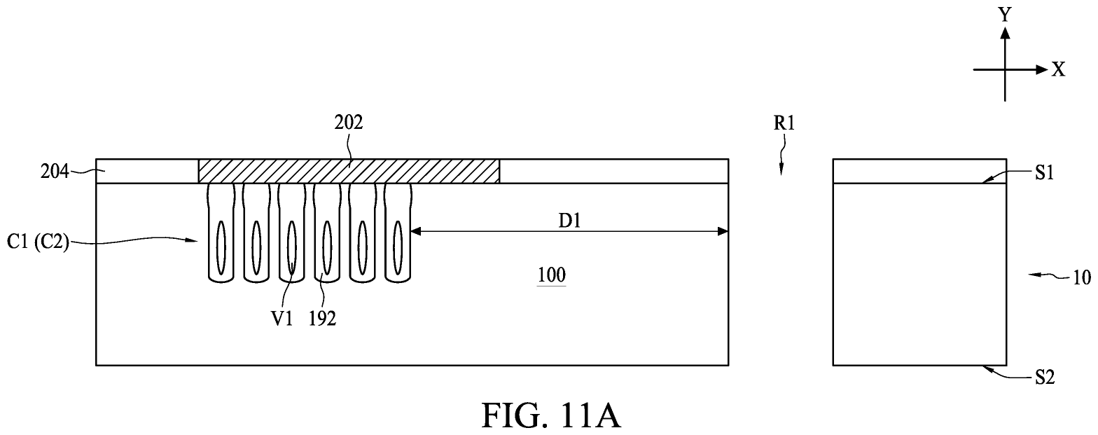

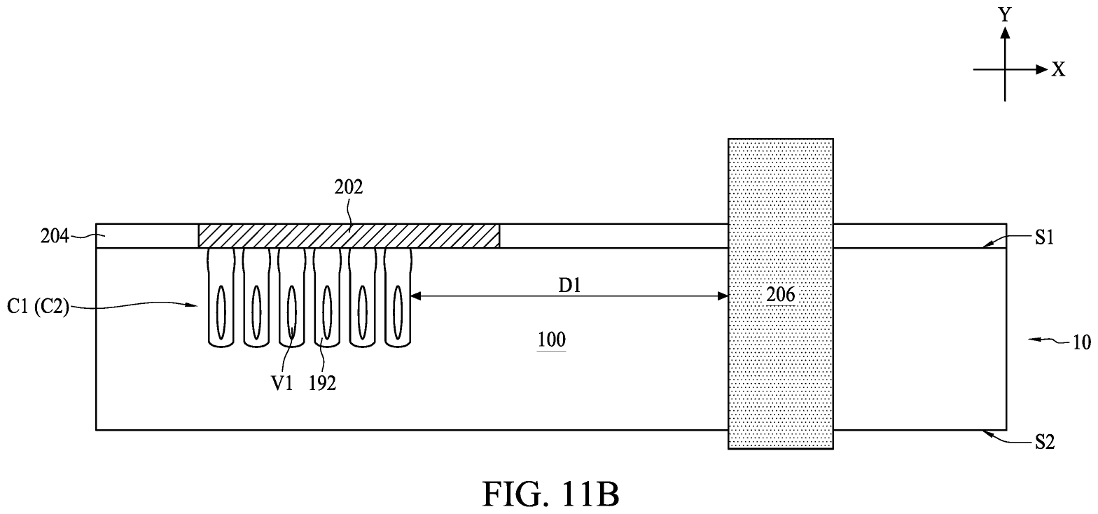

Referring to FIGS. 11A, 11B, 8D and 8E, in some embodiments, when the longitudinal length L1 of the void V1 is between about 25% and about 65% of the depth H1 of the trench T1, the predetermined distance D1 between the MIM capacitors C1, C2 and the TSV 206 is between about 3 μm and 10 μm.

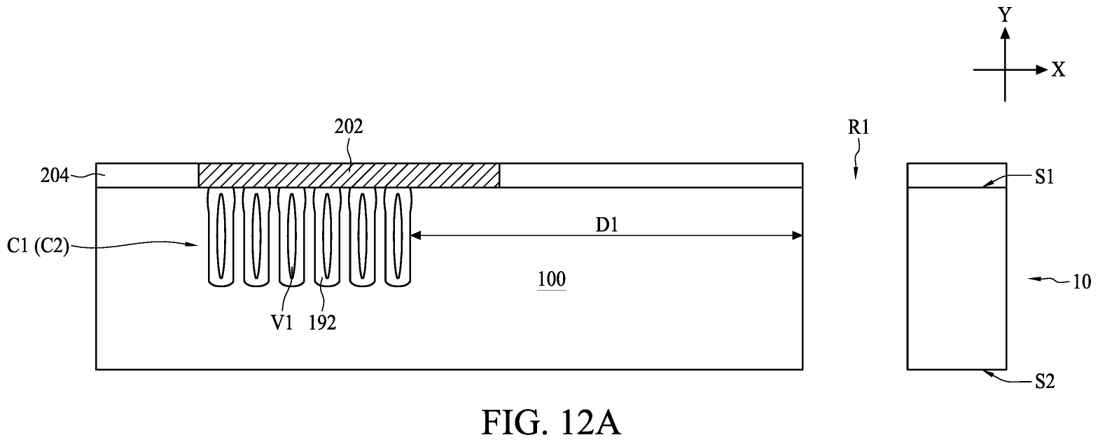

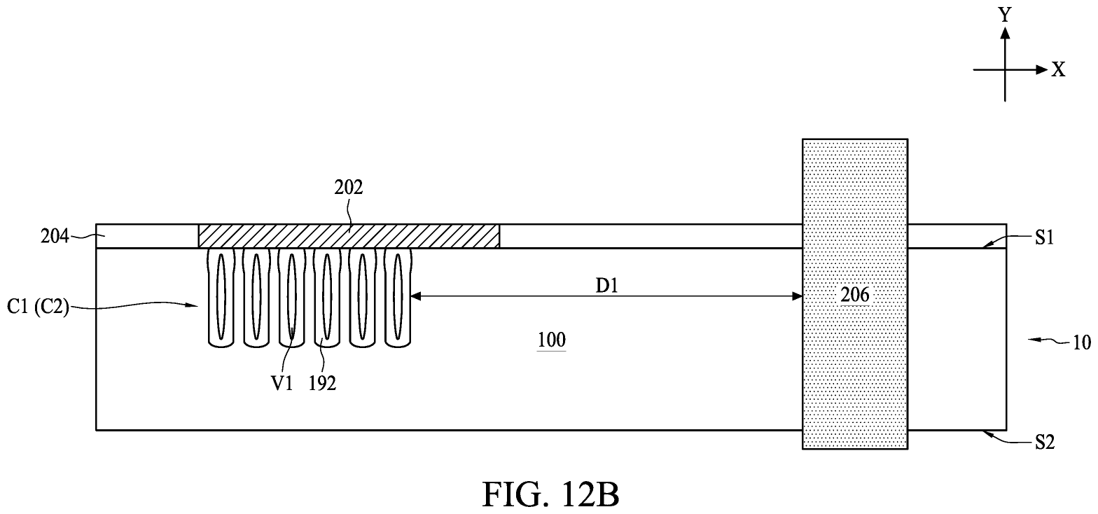

Referring to FIGS. 12A, 12B, 8E and 8F, in some embodiments, when the longitudinal length L1 of the void V1 is between about 60% and about 98% of the depth H1 of the trench T1, the predetermined distance D1 between the MIM capacitors C1, C2 and the TSV 206 is between about 5 μm and 20 μm. In some embodiments, the longitudinal length L1 of the void V1 is proportional to the predetermined distance D1 between the MIM capacitors C1, C2 and the TSV 206.

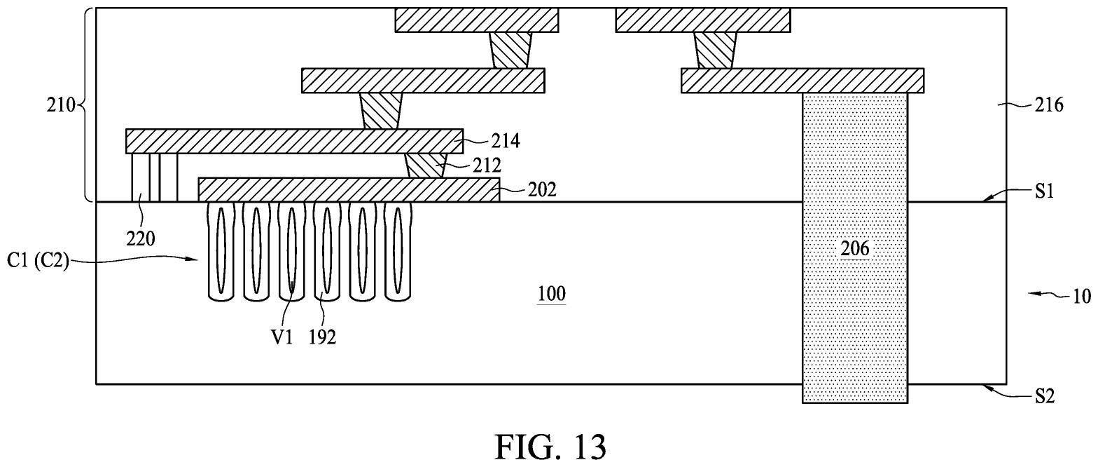

In operation 217 of FIG. 2, an interconnect structure 210 is formed on the substrate 100, as shown in FIG. 13. The formation of the interconnect structure 210 may include a series of lithographic, etch, deposition and planarization operations. The interconnect structure 210 includes multiple vertical conductive vias (such as 212) and multiple horizontal conductive lines (such as 214) which are surrounded by a dielectric layer 216. The conductive vias and conductive lines may be electrically coupled to each other. The vertical conductive vias may connect the horizontal conductive lines in different layers. In the interconnect structure 210, the bottom metal line 202 is often denoted as “M0”, a first conductive line is often denoted as “M1”, and a bottommost conductive via is often denoted as “V0”, and so on. The dielectric layer 216 may be made of the same material as the dielectric layer 204. The bottom metal line 202 and the dielectric layer 204 may belong to the interconnect structure 210. In some embodiments, the interconnect structure 210 is electrically coupled to the MIM capacitors C1, C2 and the TSV 206. The MIM capacitors C1, C2 may be electrically coupled to the TSV 206 through the interconnect structure 210. The dielectric layer 216 may be denoted as an inter-layer dielectric (ILD) layer or an inter-metal dielectric (IMD) layer. The interconnect structure 210 may include redistribution layer (RDL) structures, such as the ILD layer and/or the IMD layer and conductive features (e.g., metal traces and vias) formed in alternating layers over the first surface S1 of the substrate 100.

Still referring to FIG. 13, in some embodiments, the interconnect structure 210 includes a seal ring 220 disposed on the first surface S1 of the substrate 100. The seal ring 220 is spaced apart from the MIM capacitors C1, C2. In some embodiments, one end of the seal ring 220 is electrically coupled to one of the conductive lines, and the other end of the seal ring 220 is in contact with the substrate 100. The seal ring 220 may be used to dissipate excess charges accumulated in the MIM capacitors C1, C2. For example, excess charges in the MIM capacitors C1, C2 can flow to the silicon through the interconnect structure 210 and the seal ring 220. It should be understood that the number of seal rings is not limited to that is shown in FIG. 13, which may be adjusted according to the requirement. For example, the number of seal rings 220 may be in a range from 1 to 10. In case there are multiple seal rings 220, the multiple seal rings 220 may be electrically coupled to each other through a seal ring interconnect structure (not shown).

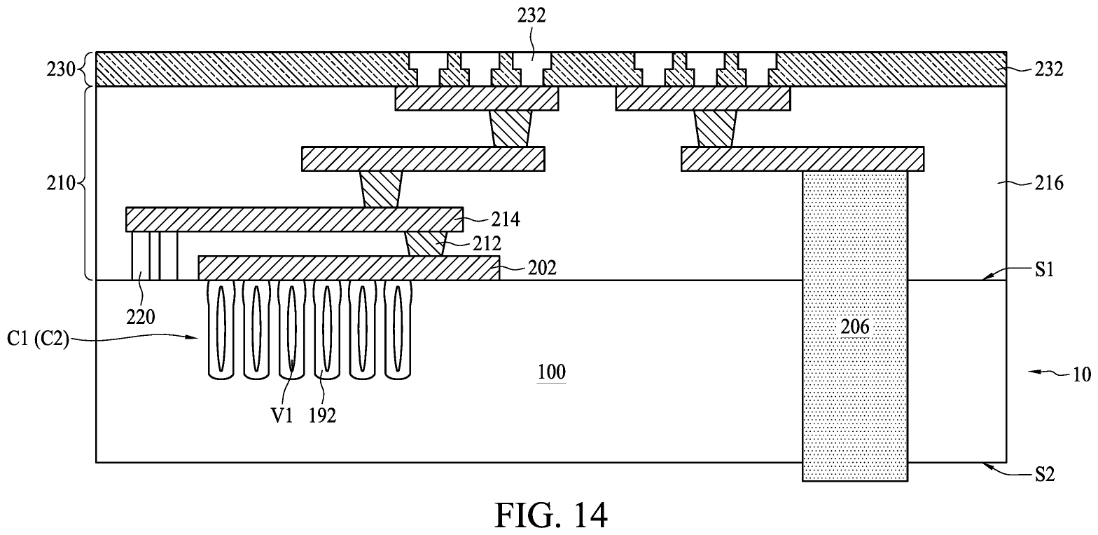

In operation 219 of FIG. 2, a bonding layer 230 is formed on the interconnect structure 210, as shown in FIG. 14. In some embodiments, the bonding layer 230 includes multiple hybrid bonding structures (HBSs) 232 embedded in a dielectric layer 234.

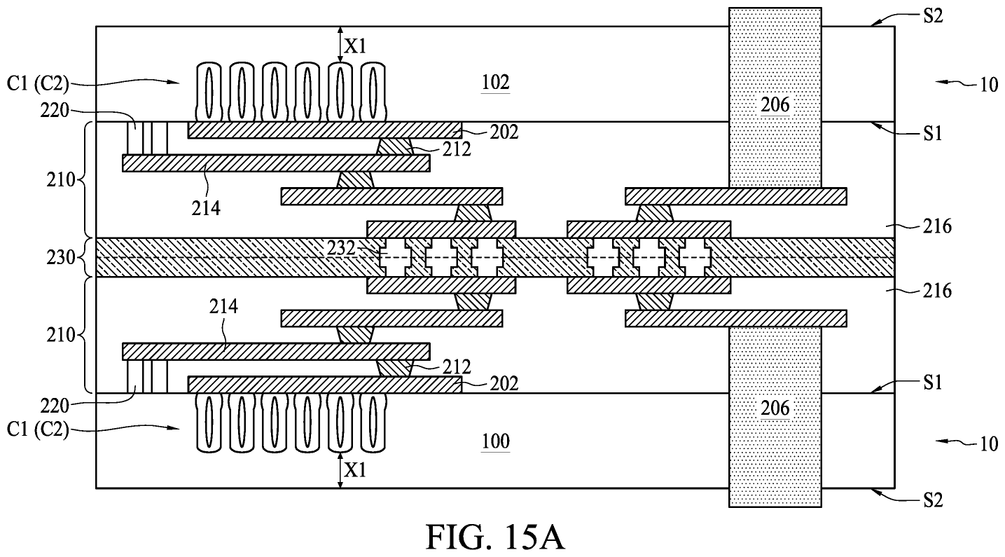

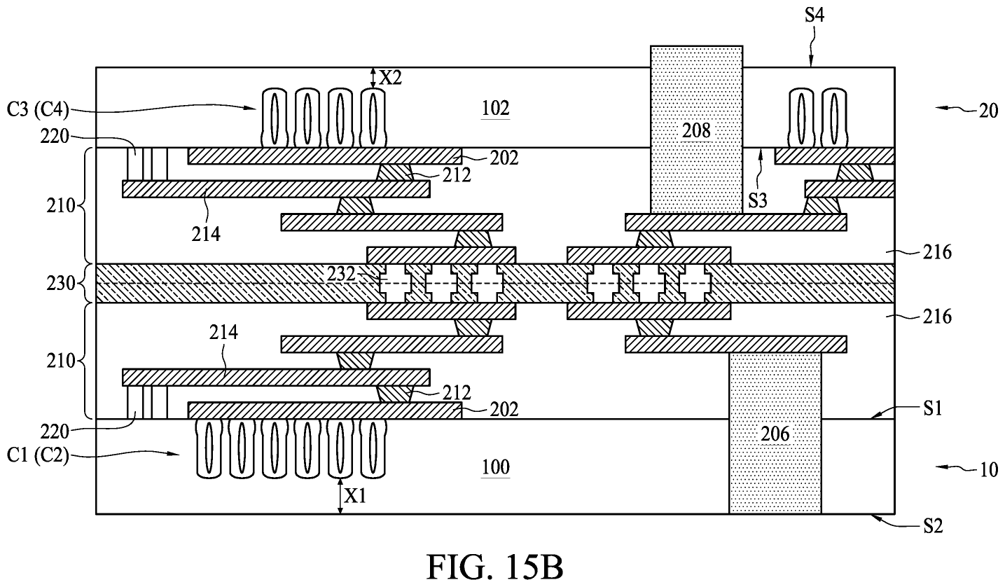

In operation 221 of FIG. 2, two semiconductor structures 10 are bonded with each other, as shown in FIG. 15A. In some embodiments, the two semiconductor structures 10 may be aligned with each other and bonded together using their respective bonding layers 230 in direct contact. In some embodiments, the HBSs 232 between the two semiconductor structures 10 are configured to be mechanically and electrically connected. The semiconductor structure 10 can be wafer-on-wafer (WOW) configuration with the semiconductor structure 10 bonded to the semiconductor structure 10. WOW devices have been widely used for various applications, such as artificial intelligence (AI) application that utilizes high performance computing. In WOW devices, a large capacitor is sometimes utilized to facilitate stable operations of the semiconductor devices, which may increase routing costs and deteriorate the reliability. The semiconductor structure 10 may allow the stacking of both similar and/or dissimilar wafers, greatly improving inter-chip interconnect density while reducing a product's form factor. The semiconductor structure 10 can provide high computing performance and high memory bandwidth to meet high performance computing (HPC) needs on clouds, data center, and high-end servers.

FIG. 15B shows another embodiment that the semiconductor structure 10 is bonded with a semiconductor structure 20. The semiconductor structure 20 is similar to the semiconductor structure 10 with a difference that MIM capacitors C3, C4 and a TSV 208 are formed in a substrate 102. The substrate 102 may be similar to the substrate 100, and the MIM capacitors C3, C4 may be similar to the MIM capacitors C1, C2. The substrate 102 has a third surface S3 and a fourth surface S4 opposite to the third surface S3. A relative position of the MIM capacitors C3, C4 and the TSV 208 in the substrate 102 may be designed. In some embodiments, the relative position of the MIM capacitors C3, C4 and the TSV 208 in the substrate 102 is different from the relative position of the MIM capacitors C1, C2 and the TSV 206 in the substrate 100. In some embodiments, a distance X2 between a bottommost point of the MIM capacitors C3, C4 and the fourth surface S4 is at least 0.8 μm.

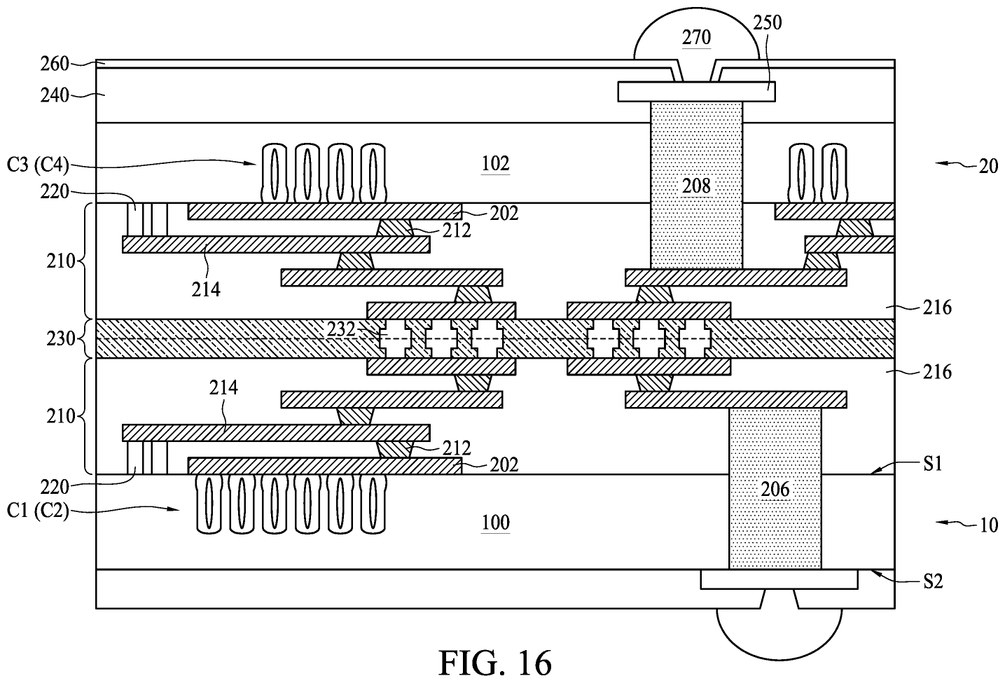

In operation 223 of FIG. 2, connection features are formed over the two semiconductor structures 10, as shown in FIG. 16 which can be continued from FIG. 15A or 15B. FIG. 16 shows the structure continued from FIG. 15B. In some embodiments, an encapsulation layer 240 respectively overlays the semiconductor structures 10 and 20. The encapsulation layer 240 may include an epoxy resin including fillers therein, a molding compound (e.g., an epoxy molding compound or other molding compound), a polyimide, a phenolic compound or material, a material including a silicone dispersed therein, or a combination thereof.

A conductive feature 250 is surrounded by the encapsulation layer 240. The conductive feature 250 is embedded within the encapsulation layer 240 and in contact with the TSV 206 or 208. A passivation layer 260 may be formed on the encapsulation layer 240 and the conductive feature 250. A connector 270, which can be a solder ball, is surrounded by the encapsulation layer 240. In some embodiments, a portion of the connector 270 is embedded within the encapsulation layer 240, and another portion of the connector 270 is exposed from the encapsulation layer 240. A portion of the conductive feature 250 exposed from the encapsulation layer 240 is coupled to the connector 270. In some embodiments, the MIM capacitors C1, C2 are electrically coupled to the TSV 206 to regulate their power, and the MIM capacitors C3, C4 are electrically coupled to the TSV 208 to regulate their power. The MIM capacitors C1, C2 and C3, C4 can be electrically coupled to their respective connector 270 through the interconnect structure 210 and the conductive feature 250. At this stage, the semiconductor device 30 including double sides of MIM capacitors are complete.

In some embodiments, the MIM capacitors within the semiconductor structure can store or hold the electrons generated from the power for driving the processing unit of a semiconductor device. The generated electrons can be of a large amount and can sometimes deteriorate or damage the semiconductor device. In some embodiments, the MIM capacitors can be used to provide the function of electrostatic discharge (ESD) and protect the semiconductor device by accumulating the electrons.

In some embodiments, the number of the capacitors can be determined according to the technical field of the applications for the product which includes the semiconductor device. For the application in the field of AI technology wherein a single giant processing unit is utilized, the MIM capacitors C1 and C2 may be disposed in the semiconductor structure 10. For other applications such as imaging processing or data computing wherein multiple small-scale processing units are utilized, a plurality of capacitors can be disposed in the semiconductor structure 10.

One aspect of the present disclosure provides a semiconductor device. The semiconductor device includes: a first semiconductor structure, including: a first substrate, having a first surface and a second surface opposite to the first surface; a first through silicon via (TSV), penetrating the first substrate; and a first deep trench capacitor (DTC), disposed in the first substrate, separated from the first TSV by a first distance and including: a first stack, including a first dielectric layer between a pair of first conductive layers in a first trench; and a first insulating layer, covering the first stack and the first trench; and a second semiconductor structure, including: a second substrate, having a third surface and a fourth surface opposite to the third surface, the third surface facing the first surface; a second TSV, penetrating the second substrate; and a second DTC, disposed in the second substrate, separated from the second TSV by a second distance and including: a second stack, including a second dielectric layer between a pair of second conductive layers in a second trench; and a second insulating layer, covering the second stack and the second trench, wherein the first insulating layer and the second insulating layer respectively surround a plurality of voids.

One aspect of the present disclosure provides a semiconductor device. The semiconductor device includes: a first semiconductor structure, including: a first substrate, having a first surface and a second surface opposite to the first surface; a first TSV, penetrating the first substrate; a first DTC, disposed in a first trench of the first substrate, the first DTC being separated from the first TSV by a first distance; and a first insulating layer covering the first DTC and the first trench and surrounding a first air gap; and a second semiconductor structure, bonded to the first semiconductor structure and including: a second substrate, having a third surface and a fourth surface opposite to the third surface; a second TSV, penetrating the second substrate; a second DTC, disposed in a second trench of the second substrate, the second DTC being separated from the second TSV by a second distance; and a second insulating layer covering the second DTC and the second trench and surrounding a second air gap; and a bonding layer, disposed between the first semiconductor structure and the second semiconductor structure.

Another aspect of the present disclosure provides a method of fabricating a semiconductor device. The method includes: providing a first substrate; forming a first trench in the first substrate; forming a first DTC in the first trench, the first DTC being separated from the first TSV by a first distance; depositing a first insulating layer to cover the first DTC and the first trench, wherein the first insulating layer surrounds a first air gap; forming a first TSV penetrating the first substrate; providing a second substrate; forming a second trench in the second substrate; forming a second DTC in the second trench, the second DTC being separated from the second TSV by a second distance; depositing a second insulating layer to cover the second DTC and the second trench, wherein the second insulating layer surrounds a second air gap; forming a second TSV penetrating the second substrate; and bonding the first substrate with the second substrate with a bonding layer between the first DTC and the second DTC.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor structure, including:
a first substrate, having a first surface and a second surface opposite to the first surface;
a first through silicon via (TSV), penetrating the first substrate; and
a first deep trench capacitor (DTC), disposed in the first substrate, separated from the first TSV by a first distance and including:
a first stack, including a first dielectric layer between a pair of first conductive layers in a first trench; and
a first insulating layer, covering the first stack and the first trench; and
a second semiconductor structure, including:
a second substrate, having a third surface and a fourth surface opposite to the third surface, the third surface facing the first surface;
a second TSV, penetrating the second substrate; and
a second DTC, disposed in the second substrate, separated from the second TSV by a second distance and including:
a second stack, including a second dielectric layer between a pair of second conductive layers in a second trench; and
a second insulating layer, covering the second stack and the second trench, wherein the first insulating layer and the second insulating layer respectively surround a plurality of voids.

2. The semiconductor device of claim 1, wherein a longitudinal length of each one of plurality of voids is proportional to the first distance or the second distance.

3. The semiconductor device of claim 2, wherein
when the longitudinal length is between about 10% and about 35% of a depth of the first trench or the second trench, the first distance or the second distance is between about 1 micrometer (μm) and 5 μm,
when the longitudinal length is between about 25% and about 65% of a depth of the first trench or the second trench, the first distance or the second distance is between about 3 μm and 10 μm, and
when the longitudinal length is between about 60% and about 98% of a depth of the first trench or the second trench, the first distance or the second distance is between about 5 μm and 20 μm.

4. The semiconductor device of claim 1, wherein the first DTC is proximal to the first surface, and the second DTC is proximal to the third surface.

5. The semiconductor device of claim 1, wherein a first bottommost point of the first DTC and the second surface are at least 0.8 μm apart, and a second bottommost point of the second DTC and the fourth surface are at least 0.8 μm apart

6. The semiconductor device of claim 1, further comprising:
a first interconnect structure, disposed on the first surface and electrically coupled to the first DTC;
a first seal ring, disposed on the first surface and electrically coupled to the first interconnect structure;
a second interconnect structure, disposed on the third surface and electrically coupled to the second DTC; and
a second seal ring, disposed on the third surface and electrically coupled to the second interconnect structure.

7. The semiconductor device of claim 1, further comprising:
a plurality of hybrid bonding structures between the first interconnect structure and the second interconnect structure.

8. The semiconductor device of claim 7, wherein at least one of the plurality of hybrid bonding structures is electrically coupled to the first interconnect structure and the second interconnect structure.

9. A semiconductor device, comprising:
a first semiconductor structure, including:
a first substrate, having a first surface and a second surface opposite to the first surface;
a first TSV, penetrating the first substrate;
a first DTC, disposed in a first trench of the first substrate, the first DTC being separated from the first TSV by a first distance; and
a first insulating layer covering the first DTC and the first trench and surrounding a first air gap; and
a second semiconductor structure, bonded to the first semiconductor structure and including:
a second substrate, having a third surface and a fourth surface opposite to the third surface;
a second TSV, penetrating the second substrate;
a second DTC, disposed in a second trench of the second substrate, the second DTC being separated from the second TSV by a second distance; and
a second insulating layer covering the second DTC and the second trench and surrounding a second air gap; and
a bonding layer, disposed between the first semiconductor structure and the second semiconductor structure.

10. The semiconductor device of claim 9, wherein the bonding layer includes:
an interconnect structure, disposed between the first surface and the third surface and including a plurality of conductive lines and a plurality of conductive vias; and
a plurality of hybrid bonding structures, connected to at least one of the plurality of conductive lines.

11. The semiconductor device of claim 10, further comprising: a seal ring, electrically coupled to the interconnect structure.

12. The semiconductor device of claim 11, wherein the seal ring is spaced apart from the first DTC and in contact with the first substrate.

13. The semiconductor device of claim 9, wherein a longitudinal length of the first air gap is proportional to the first distance, and a longitudinal length of the second air gap is proportional to the second distance.

14. The semiconductor device of claim 13, wherein the longitudinal length of the first air gap is between about 10% and about 98% of a depth of the first trench, and the longitudinal length of the second air gap is between about 10% and about 98% of a depth of the second trench.

15. A method of fabricating a semiconductor device, comprising:
providing a first substrate;
forming a first trench in the first substrate;
forming a first DTC in the first trench, the first DTC being separated from the first TSV by a first distance;
depositing a first insulating layer to cover the first DTC and the first trench, wherein the first insulating layer surrounds a first air gap;
forming a first TSV penetrating the first substrate;
providing a second substrate;
forming a second trench in the second substrate;
forming a second DTC in the second trench, the second DTC being separated from the second TSV by a second distance;
depositing a second insulating layer to cover the second DTC and the second trench, wherein the second insulating layer surrounds a second air gap;
forming a second TSV penetrating the second substrate; and
bonding the first substrate with the second substrate with a bonding layer between the first DTC and the second DTC.

16. The method of claim 15, wherein the depositing of the first insulating layer and the second insulating layer includes leaving a longitudinal length of the first air gap or the second air gap between about 10% and about 98% of a depth of the first trench or the second trench.

17. The method of claim 15, wherein a distance between the first TSV and the first DTC or between the second TSV and the second DTC is based on a size of the first air gap or the second air gap.

18. The method of claim 17, wherein when the size of the first air gap becomes greater, the first TSV is disposed farther from the first DTC, and when the size of the second air gap becomes greater, the second TSV is disposed farther from the second DTC.

19. The method of claim 15, wherein the bonding of the first substrate with the second substrate uses a plurality of hybrid bonding structures embedded in a dielectric layer and between the first substrate and the second substrate.

20. The method of claim 15, wherein the bonding layer electrically couples the first DTC to the second DTC through a plurality of conductive lines and conductive vias.
